(19) United States
(12) Patent Application Publication
(10) Pub. No.: US 2026/0068109 A1
(43) Pub. Date: Mar. 5, 2026

(54) POWER SUPPLY DEVICE

(71) Applicant: Delta Electronics (Thailand) Public Company Limited, Samutprakarn (TH)

(72) Inventors: Yuesen Guo, Shanghai (CN); Shiwei Liu, Shanghai (CN); Yong Huang, Shanghai (CN); Kai Dong, Shanghai (CN)

(21) Appl. No.: 19/307,912

(22) Filed: Aug. 22, 2025

(30) Foreign Application Priority Data
Aug. 30, 2024 (CN) 202422124417.0
Nov. 11, 2024 (CN) 202422743209.9

(51) Int. Cl. H05K 7/20; H01F 27/24; H01F 27/28; H05K 1/18

(52) U.S. Cl. CPC H05K 7/2089; H01F 27/24; H01F 27/28; H05K 1/181; H05K 2201/10015

(57) ABSTRACT

A power supply device is disclosed and includes a transformer unit, a rectifier unit and a heat dissipation component. The transformer unit includes a first winding, a second winding and a magnetic core. The rectifier unit includes a circuit board, a plurality of rectifiers and a plurality of output filter capacitors. The circuit board and the transformer unit are disposed adjacent to each other, and the second winding is electrically connected to the circuit board, wherein the circuit board has a first side and a second side opposite to each other, and the first side faces the transformer unit. The heat dissipation component covers a rectification module formed by the transformer unit and the rectifier unit.

### CROSS-REFERENCE TO RELATED APPLICATION

This application claims priorities to China Patent Application No. 202422124417.0 filed on Aug. 30, 2024, and China Patent Application No. 202422743209.9 filed on Nov. 11, 2024. The entire contents of the above-mentioned patent applications are incorporated herein by reference for all purposes.

### FIELD OF THE INVENTION

The present disclosure relates to an assembly structure of electronic components, and more particularly to a power supply device.

### BACKGROUND OF THE INVENTION

With the explosive growth of data volume, traditional air cooling technology has been unable to meet the cooling requirements of high-power-density servers. Cold plate technology, as an efficient and green cooling method, is gradually becoming the best choice for data center construction.

As one of the main heat-generating elements inside the server power supply, the rectification module (combination of transformer and rectifier) has a complex mechanism. How to carry out comprehensive heat dissipation through the cold plate (which can dissipate heat for the transformer and the rectifier at the same time) is one of the key technologies in the design of cold plate power supply. Generally, the components with heat dissipation requirements in the rectification module mainly include the transformer winding and transformer magnetic core in the transformer unit, and the rectifier in the rectifier unit.

On the other hand, for the design of server power supply, since the highest efficiency is required at half load, the winding loss and the core loss of the transformer are often designed to be close to the same at half load. As the server power supply is designed in this way, the winding loss is increased by four times, but the core loss remains basically unchanged. Therefore, cooling the windings becomes one of the key considerations in this type of design. Sometimes it is even possible to sacrifice the heat dissipation for the magnetic core, so as to provide better heat dissipation for the windings.

In view of this, there is a need of providing a power supply device arranging and combining the components in the transformer unit and the rectifier unit with a cold plate on top, so as to optimize the heat dissipation performance, and obviate the drawbacks encountered by the prior arts.

### SUMMARY OF THE INVENTION

In accordance with the present disclosure, a power supply device is provided and includes a transformer unit, a rectifier unit and a heat dissipation component. The transformer unit includes a first winding, a second winding and a magnetic core. The rectifier unit includes a circuit board, a plurality of rectifiers and a plurality of output filter capacitors. The circuit board and the transformer unit are disposed adjacent to each other, and the second winding is electrically connected to the circuit board, wherein the circuit board has a first side and a second side opposite to each other, and the first side faces the transformer unit. The heat dissipation component covers a rectification module formed by the transformer unit and the rectifier unit.

### BRIEF DESCRIPTION OF THE DRAWINGS

The above contents of the present disclosure will become more readily apparent to those ordinarily skilled in the art after reviewing the following detailed description and accompanying drawings, in which:

FIG. 1 is a structural exploded view illustrating a power supply device according to a first embodiment of the present disclosure;

FIG. 2 is a structural exploded view illustrating the transformer unit according to the first embodiment of the present disclosure;

FIG. 3 is a structural perspective view illustrating the transformer unit according to the first embodiment of the present disclosure;

FIG. 4 is a cross-sectional structural view illustrating the power supply device according to the first embodiment of the present disclosure;

FIG. 5 is a cross-sectional structural view illustrating a power supply device according to a second embodiment of the present disclosure;

FIG. 6 is a cross-sectional structural view illustrating a power supply device according to a third embodiment of the present disclosure;

FIG. 7 is a cross-sectional structural view illustrating a power supply device according to a fourth embodiment of the present disclosure;

FIG. 8 is a cross-sectional structural view illustrating a power supply device according to a fifth embodiment of the present disclosure;

FIG. 9 is a cross-sectional structural illustrating a power supply device according to a sixth embodiment of the present disclosure;

FIG. 10 is a structural exploded view illustrating a transformer unit according to a seventh embodiment of the present disclosure;

FIG. 11 is a structural perspective view illustrating the transformer unit according to the seventh embodiment of the present disclosure;

FIG. 12 is a structural exploded view illustrating a transformer unit according to an eighth embodiment of the present disclosure;

FIG. 13 is a structural perspective view illustrating the transformer unit according to the eighth embodiment of the present disclosure;

FIG. 14 is a cross-sectional structural view illustrating the power supply device according to the eighth embodiment of the present disclosure;

FIG. 15 is a cross-sectional structural view illustrating a power supply device according to a ninth embodiment of the present disclosure;

FIG. 16 is a structural exploded view illustrating a transformer unit according to a tenth embodiment of the present disclosure;

FIG. 17 is a structural perspective view illustrating the transformer unit according to the tenth embodiment of the present disclosure; and

FIG. 18 is a cross-sectional structural view illustrating a power supply device according to an eleven embodiment of the present disclosure.

### DETAILED DESCRIPTION

The present disclosure will now be described more specifically with reference to the following embodiments. It is to be noted that the following descriptions of embodiments of this disclosure are presented herein for purpose of illustration and description only. It is not intended to be exhaustive or to be limited to the precise form disclosed. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals or letters in the various examples. This repetition is for the purpose of simplicity and clarity and does not in itself dictate a relationship between the various embodiments or configurations discussed. Further, spatially relative terms, such as “upper,” “lower,” “left,” “right” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. When an element is referred to as being “connected,” or “coupled,” to another element, it can be directly connected or coupled to the other element or intervening elements may be present. Although the wide numerical ranges and parameters of the present disclosure are approximations, numerical values are set forth in the specific examples as precisely as possible. In addition, although the “first,” “second,” and the like terms in the claims be used to describe the various elements can be appreciated, these elements should not be limited by these terms, and these elements are described in the respective embodiments are used to express the different reference numerals, these terms are only used to distinguish one element from another element. For example, a first element could be termed a second element, and, similarly, a second element could be termed a first element, without departing from the scope of example embodiments. Besides, “and/or” and the like may be used herein for including any or all combinations of one or more of the associated listed items.

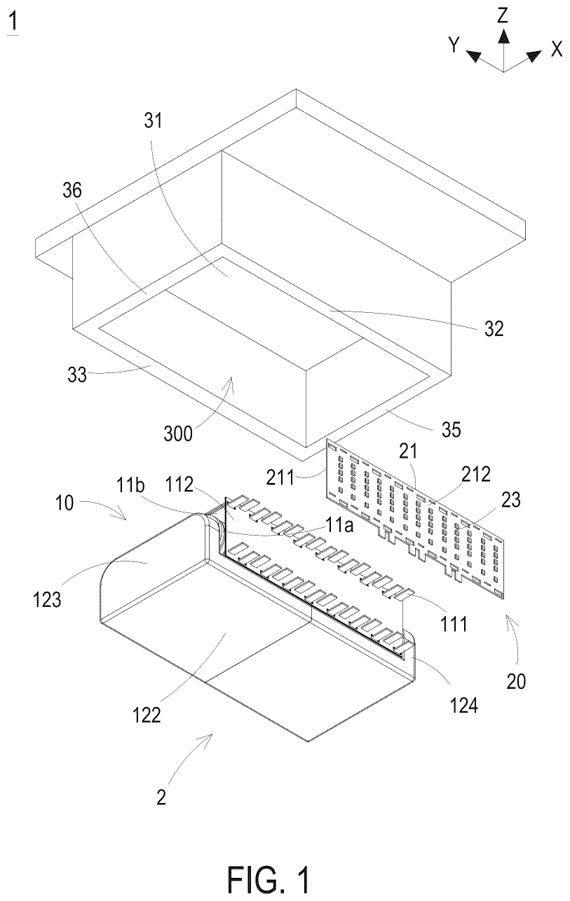

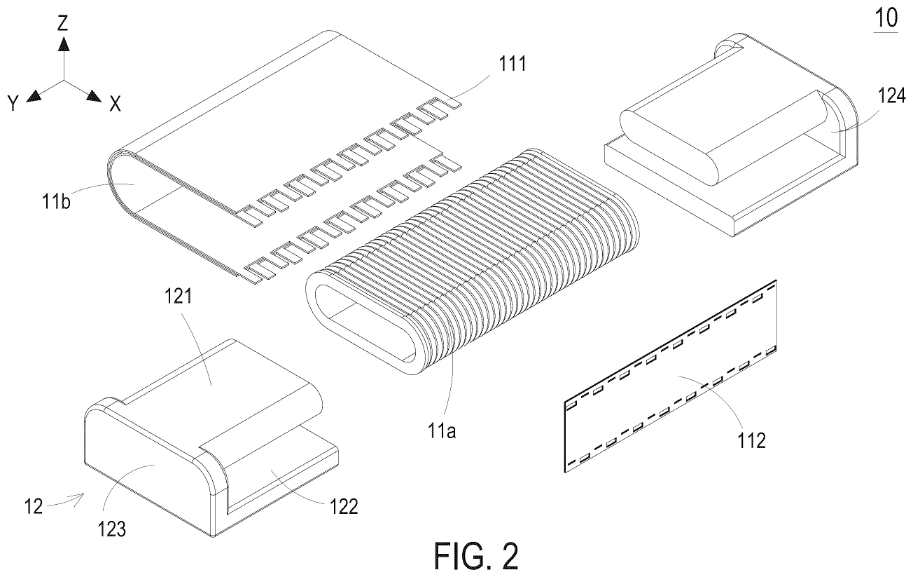

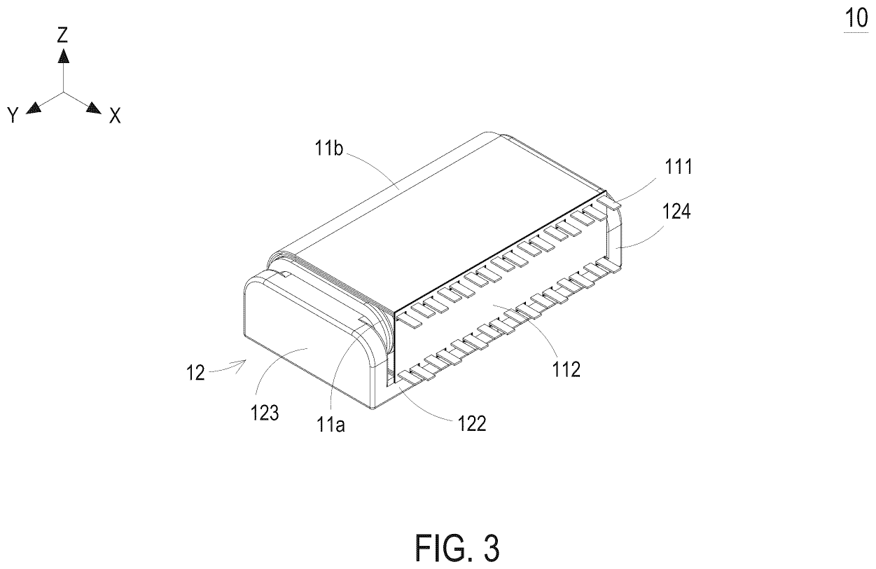

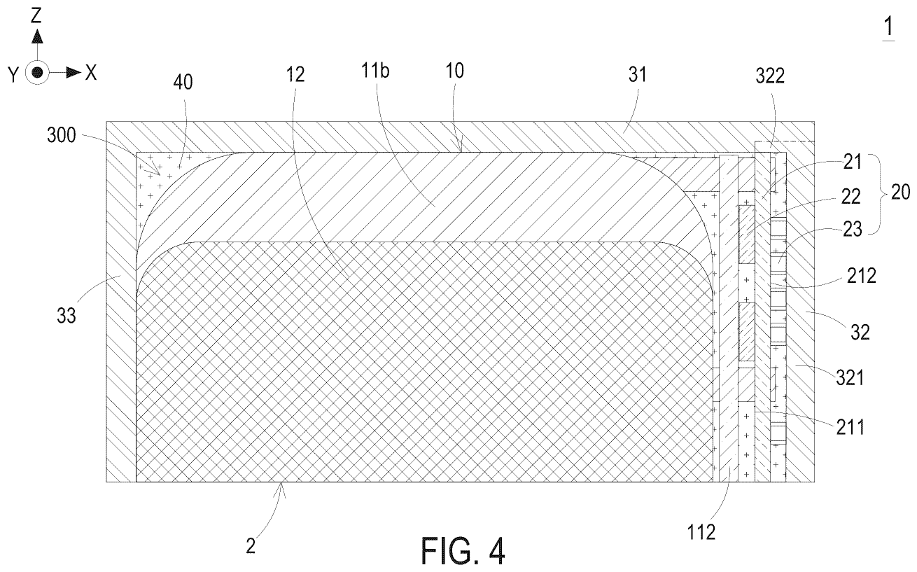

FIG. 1 is a structural exploded view illustrating a power supply device according to a first embodiment of the present disclosure. FIG. 2 is a structural exploded view illustrating the transformer unit according to the first embodiment of the present disclosure. FIG. 3 is a structural perspective view illustrating the transformer unit according to the first embodiment of the present disclosure. FIG. 4 is a cross-sectional structural view illustrating the power supply device according to the first embodiment of the present disclosure. In the embodiment, a power supply device 1 is provided and includes a transformer unit 10, a rectifier unit 20 and a heat dissipation component 31. The transformer unit 10 and the rectifier unit 20 are integrated to form a rectification module 2. The transformer unit 10 includes a first winding 11a, a second winding 11b and a magnetic core 12. The magnetic core 12 includes a first magnetic column 121 and a second magnetic column 122. The first winding 11a is wound around the first magnetic column 121, and the second winding 11b is wound outside the first winding 11a. In the embodiment, the magnetic core 12 further includes two magnetic covers 123, 124, and the first magnetic column 121 and the second magnetic column 122 are connected between the two magnetic cover 123, 124. In the embodiment, the rectifier unit 20 includes a circuit board 21, a plurality of rectifiers 22 and a plurality of output filter capacitors 23. The circuit board 21 and the transformer unit 10 are disposed adjacent to each other. The second winding 11b is electrically connected to the circuit board 21. Preferably but not exclusively, in the embodiment, the first winding 11a is made of litz wire wound thereon. Preferably but not exclusively, the second winding 11b are made of copper foil, and the pins 111 of the second winding 11b are connected to the circuit board 21 of the rectifier unit 20. In the embodiment, the circuit board 21 has a first side 211 and a second side 212 opposite to each other, and the first side 211 faces the transformer unit 10. In the embodiment, the plurality of rectifiers 22 are disposed on the first side 211 of the circuit board 21, and the plurality of output filter capacitors 23 are disposed on the second side 212 of the circuit board 21. In the embodiment, the rectification module 2 formed by the transformer unit 10 and the rectifier unit 20 are arranged between the heat dissipation component 31 and a main board 9 for the power supply device 1. Preferably but not exclusively, the heat dissipation component 31 covers the rectification module 2. The first magnetic column 121 is arranged between the heat dissipation component 31 and the second magnetic column 122. The heat dissipation component 31 includes an inlet end and an outlet end and is connected to an external refrigeration source. The external refrigerant is sent into the heat dissipation component 31 and finally returns to the external refrigeration source to achieve cyclic cooling. In some embodiments, the heat dissipation component 31 is a cold plate. Preferably but not exclusively, the refrigerant is water, ethanol, or other coolant. It should be understood that the length of the heat dissipation component 31 and the power supply device 1 along the X-axis direction are consistent. The heat dissipation component 31 is used to dissipate heat generated from devices in the entire power supply device 1, including but not limited to the rectification module 2. For the convenience of explanation, the length of the heat dissipation component 31 of the present disclosure is basically the same as the length of the rectification module 2 along the X-axis direction, and is only for illustration.

In the embodiment, the heat dissipation component 31 is disposed adjacent to a top side of the second winding 11b. The circuit board 21 of the rectifier unit 20 and the transformer unit 10 are disposed along a horizontal direction (i.e., the X-axis direction). In the embodiment, the transformer unit 10 and the rectifier unit 20 are arranged horizontally under the heat dissipation component 31 in the Y-axis direction, and two U-shaped magnetic cores are used in the transformer unit 10 to form the first magnetic column 121, the second magnetic column 122 and the two magnetic covers 123. 124. The first winding 11a and the second winding 11b are wound around the upper first magnetic column 121, so as to face the heat dissipation component 31. It allows disposing the top side of the second winding 11b adjacent to the heat dissipation component 31 for heat dissipation.

Notably, the first winding 11a and the second winding 11b are not limited to being composed of litz wire or copper foil. In the embodiment, the second winding 11b of the transformer unit 10 is connected to the circuit board 21 of the rectifier unit 20 through the lateral pins, and the pins 111 of the second winding 11b are inserted into the circuit board 21 of the rectifier unit 20 through the substrate 112.

In the embodiment, the transformer unit 10 and the rectification unit 20 are both accommodated in the accommodation 300. The accommodation slot 300 is filled with thermal conductive glue 40 to dissipate heat generated from the transformer unit 10 and the rectifier unit 20. In the embodiment, the top of the accommodation slot 300 is formed by the heat dissipation component 31. Preferably but not exclusively, the accommodation slot 300 is a glue-filled sealed space surrounded by four lateral plates 32, 33, 35, 36. In one embodiment, each lateral plate 32, 33, 35, 36 of the accommodation slot 300 is a metal plate. Certainly, in other embodiments, the metal plate includes a flow channel (not shown) disposed therein. In other words, the heat dissipation component 31 can for example be served as a top plate of the accommodation slot 300 can for example be formed, so as to form a slot to accommodate the transformer unit 10 and the rectifier unit 20. In the embodiment, the accommodation slot 300 includes a plurality of lateral plates 32, 33, 35, 36, and the accommodation slot 300 is integrally formed with the heat dissipation component 31. In other embodiments, each of the lateral plates 32, 33, 35, 36 of the accommodation slot 300 can be enclosed and then fixed with the heat dissipation component 31 to form the accommodation slot 300. The present disclosure is not limited thereto. Certainly, the size, the shape and the structure of the accommodation slot 300 are adjustable according to the practical requirements, and the present disclosure is not limited thereto.

In some embodiments, the second winding 11b and the plurality of output filter capacitors 23 are arranged on two opposite sides of the circuit board 21, respectively, so that the plurality of output filter capacitors 23 are disposed adjacent to the first lateral plate 32 for heat dissipation. Since the lateral plates 32, 33, 35, 36 of the accommodation slot 300 are the metal plates, it is conducive to transferring heat to heat dissipation component 31. Thereby, the power supply device 1 can exert the best heat dissipation effect. Furthermore, the plurality of rectifiers 22 in the rectifier unit 20 are placed on the first side 211 of the circuit board 21 facing the transformer unit 10 to minimize the AC loss. Since the plurality of output filter capacitors 23 are the filter capacitors at the output end of the rectifier circuit, the capacitors will have large ripples and serious heat generation in low-voltage and high-current situations, and the temperature has a greater impact on the life of the capacitors. Although this issue can be solved by adding more capacitors, such an arrangement will take up a certain amount of space. Alternatively, if the plurality of output filter capacitors 23 can be well dissipated, the overall power density will be improved. In the present disclosure, the plurality of output filter capacitors 23 are disposed adjacent to the first lateral plate 32, so that the heat dissipation advantages of the heat dissipation component 31 is fully utilized to take away the heat generated by the plurality output filter capacitors 23 to ensure the life of the output filter capacitors 23. It allows fewer capacitors can be used to achieve filtering while meeting the heat dissipation requirements and improving the overall power density. On the other hand, the plurality of rectifiers 22 in the rectifier unit 20 face the transformer unit 10 rather than facing the lateral plate 32 for heat dissipation. When the transformer unit 10 and the rectifier unit 20 are in operation, the first harmonic in the secondary current of the transformer mainly flows through the rectifiers 22, and the second harmonic and the above one mainly flow through the filter capacitors. The amplitude of the first harmonic is relatively larger. In the embodiment, since the rectifiers 22 are disposed on the first side 211 facing the transformer 10 to form the shortest current loop path, it helps to reduce the loss of the rectifiers 22 and the loss of the rectifier circuit board 21. On the contrary, if the rectifiers 22 is disposed on the second side 212 of the circuit board 21 and adjacent to the first lateral plate 32, a longer current loop path away from the transformer unit 10 is formed, and the loss is increased. Notably, since the number of output filter capacitors 23 is generally large, in some embodiments, a part of the output filter capacitors 23 are disposed on one side and attached to the first lateral plate 32, and the remaining part of the output filter capacitors 23 and the rectifiers 22 are disposed on another side. Certainly, the present disclosure is not limited thereto.

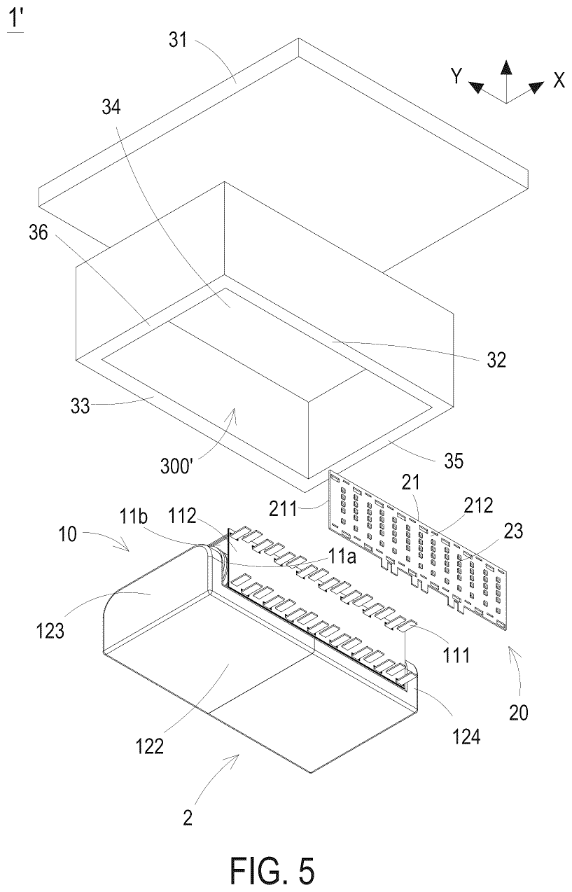

FIG. 5 is a cross-sectional structural view illustrating a power supply device according to a second embodiment of the present disclosure. In the embodiment, the structures, elements and functions of the power supply device 1′ are similar to those of the power supply device 1 of FIG. 1 to FIG. 4, and are not redundantly described herein. In the embodiment, the accommodation slot 300′ includes a plurality of lateral plates 32, 33, 35, 36 and a top plate 34 for forming a slot to accommodate the transformer unit 10 and the rectifier unit 20, and the heat dissipation component 31 covers the top plate 34. Since the accommodation slot 300′and the heat dissipation component 31 are disposed separately, it is easier to modularize after the accommodation slot 300′ is filled with the glue. Certainly, the present disclosure is not limited thereto.

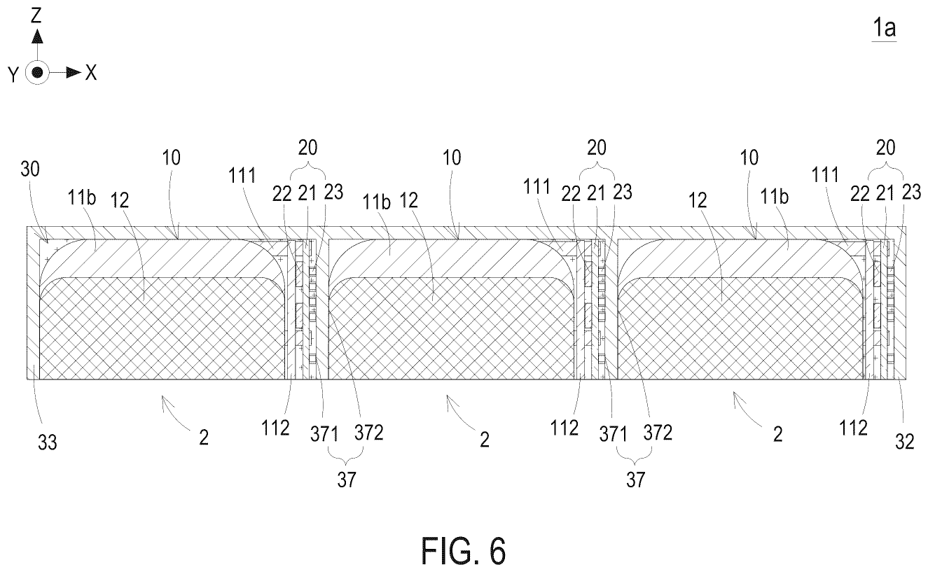

FIG. 6 is a cross-sectional structural view illustrating a power supply device according to a third embodiment of the present disclosure. In the embodiment, the structures, elements and functions of the power supply device 1a are similar to those of the power supply device 1 of FIG. 1 to FIG. 4, and are not redundantly described herein. In the embodiment, the power supply device 1a includes three transformer units 10 and three rectifier units 20 that are sequentially and alternately arranged along the horizontal direction (i.e., the X-axis direction) to form three rectification modules 2 adjacent to each other in the accommodation slot 30. Moreover, the heat dissipation component 31 is disposed adjacent to the top sides of the second windings 11b of the three transformer units 10. In the embodiment, the accommodation slot 30 include two lateral plates 37 shared by the three rectification modules 2. The two shared lateral plates 37 are extended downward from the heat dissipation component 31 and located between each adjacent two of the three rectification modules 2. In the embodiment, each of the two shared lateral plates 37 has a first lateral side 371 and a second lateral side 372 opposite to each other. The first lateral side 371 is disposed adjacent to the output filter capacitors 23 in the left of each adjacent two of the three rectification modules 2, and the second lateral side 372 is disposed adjacent to one lateral side of the second winding 11b in the right of each adjacent two of the three rectification modules 2. The lateral side of the second winding 11b enables the power supply device 1a to exert the best heat dissipation effect. In this way, the power supply device 1a can exert the best heat dissipation effect. In other embodiments, the power supply device 1a includes N transformer units 10 and N rectifier units 20 sequentially and alternately arranged along the horizontal direction (i.e., the X-axis direction) to form N rectification modules 2. The N rectification modules 2 are arranged adjacently. The heat dissipation component 31 is disposed adjacent to the top sides of the second windings 11b in the N transformer units 10, and the N rectification modules 2 include (N−1) shared lateral plates 37. Moreover, the (N−1) shared lateral plates 37 are extended downward from the heat dissipation component 31 and located between each adjacent two of the N rectification modules 2. N is an integer, and N≥2. In this way, the plurality of transformer units 10 and the plurality of rectifier units 20 are sequentially and alternately arranged to form the plurality of rectification modules 2, and the plurality of rectifier modules 2 are arranged adjacently. The heat dissipation component 31 is disposed adjacent to the top sides of the second windings 11b in the plurality of transformer units 10 for heat dissipation, and the plurality of shared lateral plates 37 are extended downward from the heat dissipation component 31 and located between each adjacent two of the plurality of rectification modules 2. The first lateral side 371 of the shared lateral plate 37 is disposed adjacent to the output filter capacitors 23 in the left of each adjacent two of the rectification modules 2, and the second lateral side 372 of the shared lateral plate 37 is disposed adjacent to one side of the second winding 11b in the right of each adjacent two of the rectification modules 2. Thereby, the power supply device 1a can exert the best heat dissipation effect. Certainly, the present disclosure is not limited thereto.

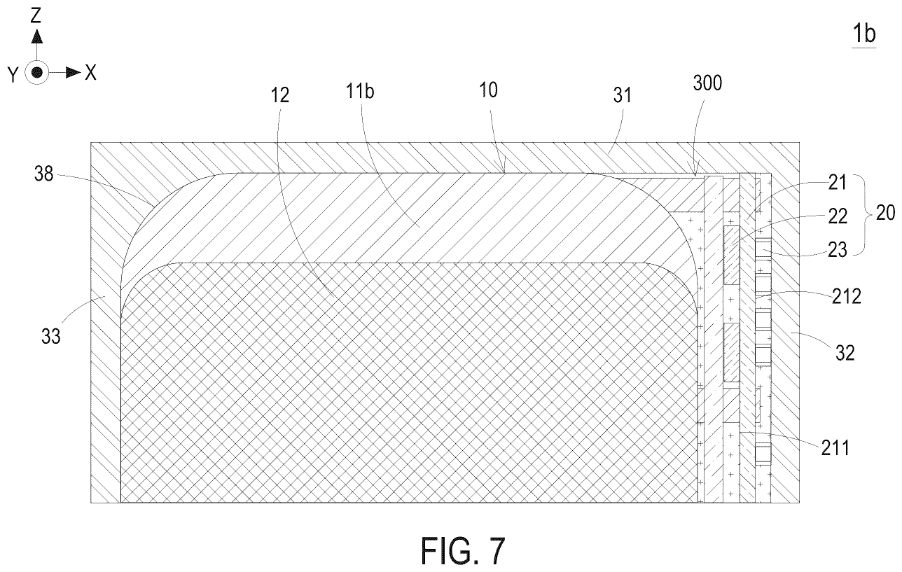

FIG. 7 is a cross-sectional structural view illustrating a power supply device according to a fourth embodiment of the present disclosure. In the embodiment, the structures, elements and functions of the power supply device 1b are similar to those of the power supply device 1 of FIG. 1 to FIG. 4, and are not redundantly described herein. In the embodiment, the heat dissipation component 31 has an edge connected to the side plate 33 to form an arc surface 34 that fits a shape of the second winding 11b. Thereby, the area of the second winding 11b for heat dissipation through the heat dissipation component 31 is increased. Certainly, the present disclosure is not limited thereto.

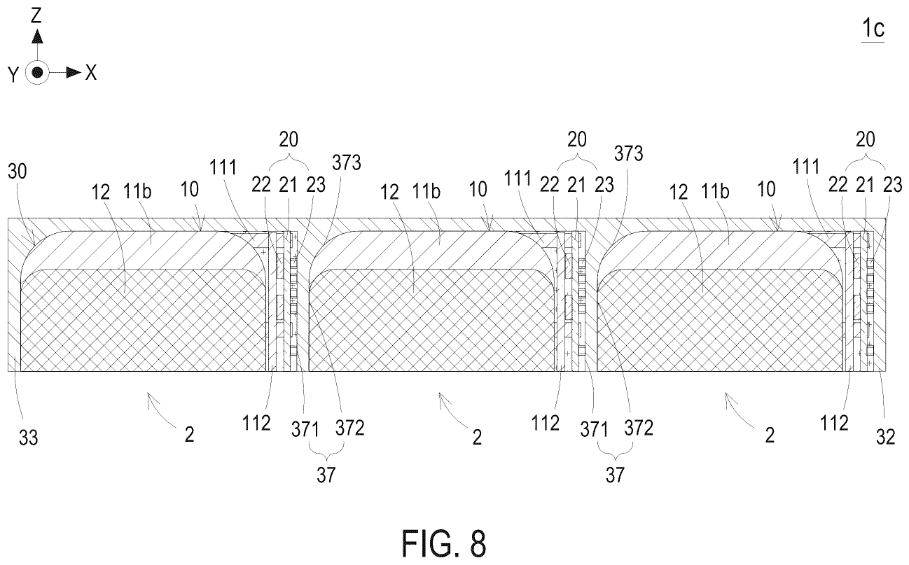

FIG. 8 is a cross-sectional structural view illustrating a power supply device according to a fifth embodiment of the present disclosure. In the embodiment, the structures, elements and functions of the power supply device 1c are similar to those of the power supply device 1a of FIG. 6, and are not redundantly described herein. In the embodiment, a plurality of transformer units 10 and a plurality of rectification units 20 are sequentially and alternately arranged to form a plurality of rectification modules 2. In the embodiment, he plurality of rectification modules 2 are arranged adjacently, and the heat dissipation component 31 is disposed adjacent to the top sides of the second windings 11b in the plurality of transformer units 10 for heat dissipation. In addition, the plurality of shared lateral plates 37 are extended downward from the heat dissipation component 31 and located between each adjacent two of the plurality of rectification modules 2. The shared lateral plate 37 and the heat dissipation component 31 are further connected to form a fitting arc surface 373. The fitting arc surface 373 fits the shape of the corresponding second winding 11b, so as to increase the area of each second winding 11b for heat dissipation through the heat dissipation component 31. Certainly, the present disclosure is not limited thereto.

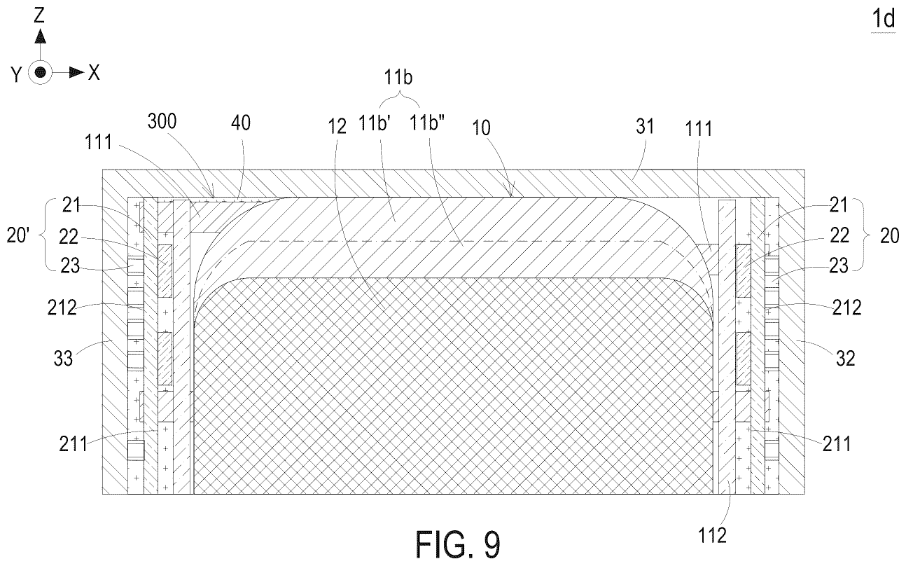

FIG. 9 is a cross-sectional structural view illustrating a power supply device according to a sixth embodiment of the present disclosure. In the embodiment, the structures, elements and functions of the power supply device 1d are similar to those of the power supply device 1 of FIG. 1 to FIG. 4, and are not redundantly described herein. In the embodiment, the power supply device 1d further includes two rectifier units 20, 20′. The second winding 11b of the transformer unit 10 includes a first sub-winding 11b′ and a second sub-winding 11b″, which are electrically connected to the circuit boards 21 of the two rectifier units 20, 20′, respectively. The circuit boards 21 of the two rectifier units 20, 20′are arranged on two opposite sides of the transformer unit 10. In the embodiment, the transformer unit 10 uses two U-shaped magnetic cores to form the first magnetic column 121 and the second magnetic column 122 arranged up and down. After the first winding 11a is wound around the upper first magnetic column 121 and then the first sub-winding 11b′ and the second sub-winding 11b″ are sequentially wound thereon, one sides of the first sub-winding 11b′ and the second sub-winding 11b″ are disposed adjacent to the heat dissipation component 31 for heat dissipation. Moreover, the circuit boards 21 of the two rectifier units 20, 20′ are arranged on two opposite sides of the transformer unit 10, so that the output filter capacitors 23 are disposed adjacent to the lateral plates 32, 33 for heat dissipation, and the optimal heat dissipation performance is achieved.

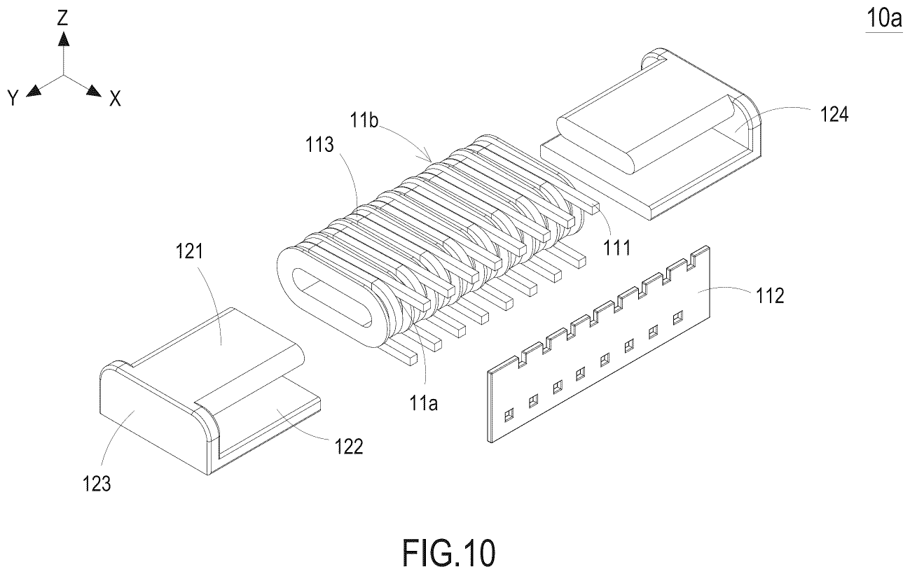

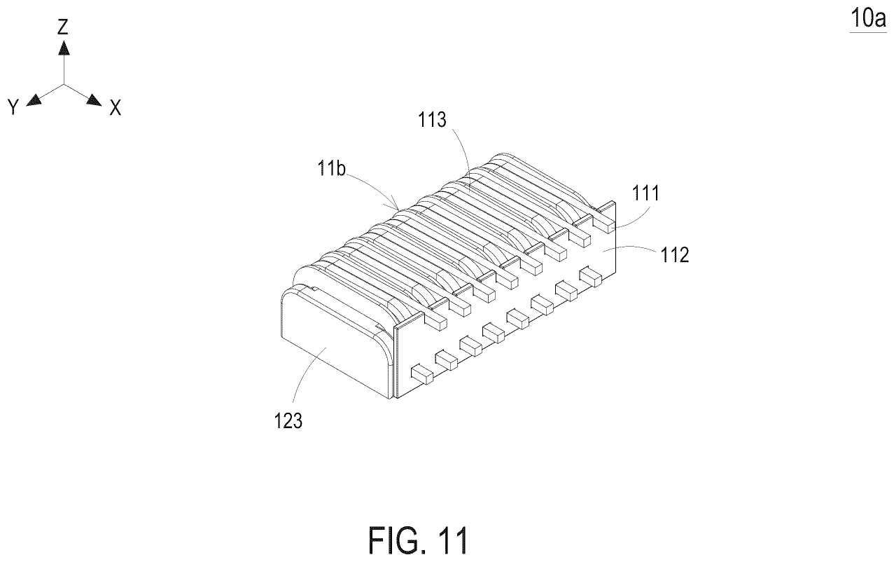

FIG. 10 is a structural exploded view illustrating a transformer unit according to a seventh embodiment of the present disclosure. FIG. 11 is a structural perspective view illustrating the transformer unit according to the seventh embodiment of the present disclosure. In the embodiment, the structures, elements and functions of the transformer unit 10a are similar to those of the transformer unit 10 of FIG. 1 to FIG. 9, and are not redundantly described herein. Preferably but not exclusively, in the embodiment, the second winding 11b is made of litz wire 113 wound thereon, and the pins 111 of the second winding 11b are connected to the circuit board 21 of the rectifier unit 20 through a substrate 112.

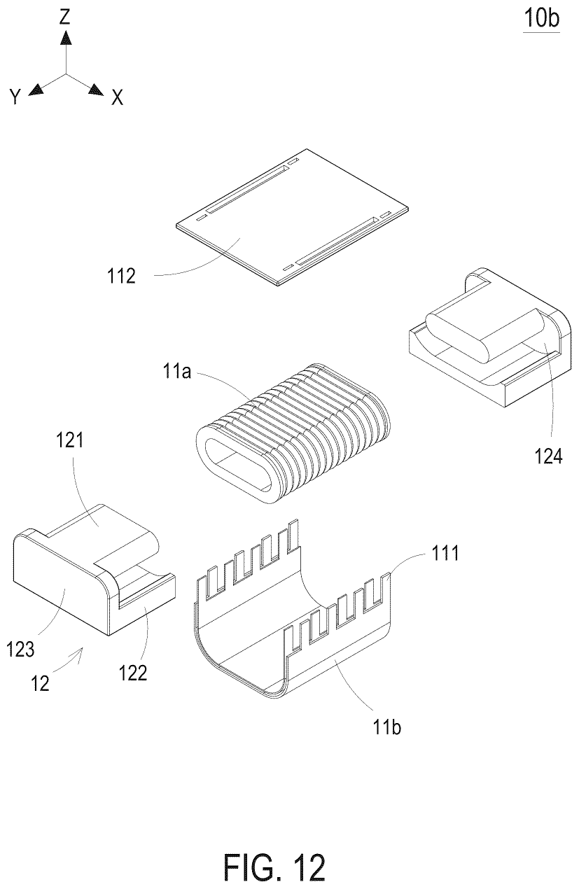

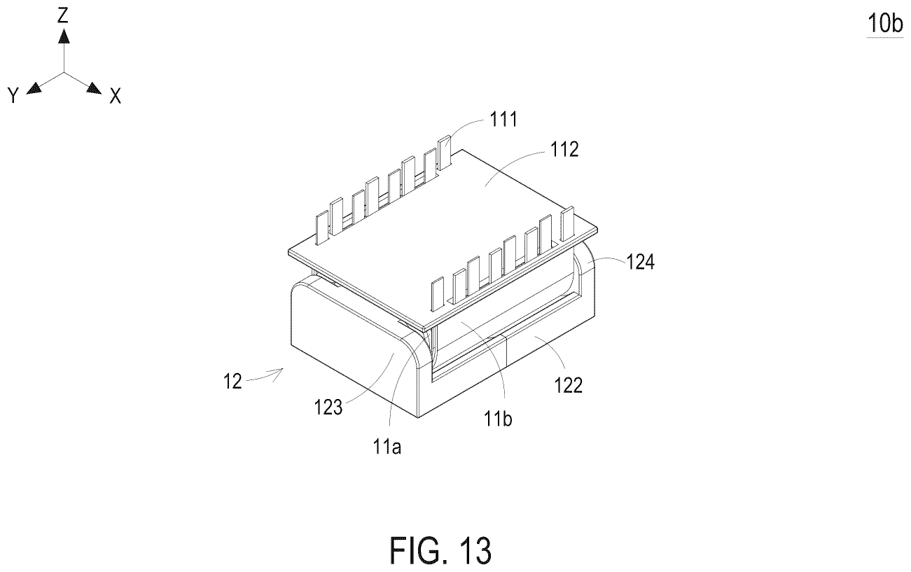

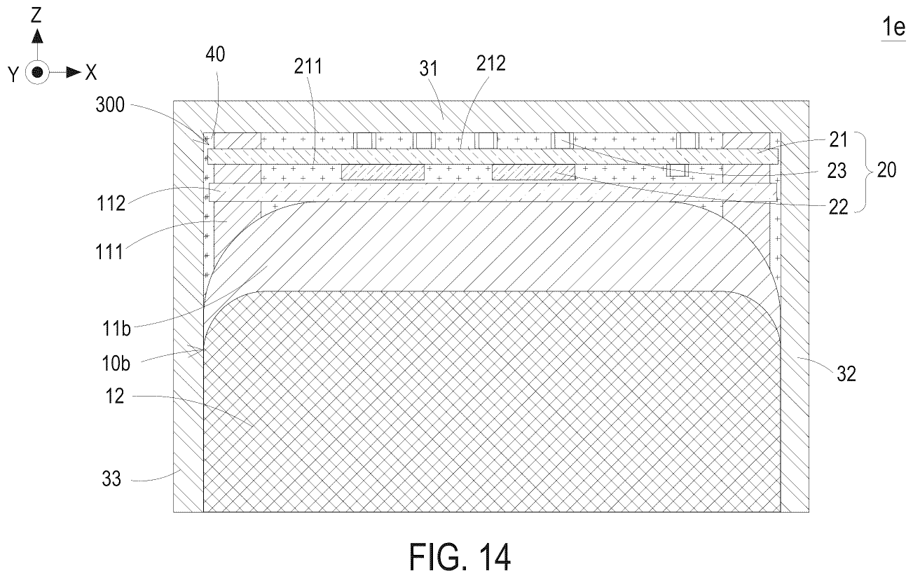

FIG. 12 is a structural exploded view illustrating a transformer unit according to an eighth embodiment of the present disclosure. FIG. 13 is a structural perspective view illustrating the transformer unit according to the eighth embodiment of the present disclosure. FIG. 14 is a cross-sectional structural view illustrating the power supply device according to the eighth embodiment of the present disclosure. In the embodiment, the structures, elements and functions of the power supply device 1e are similar to those of the power supply device 1 of FIG. 1 to FIG. 4, and are not redundantly described herein. In the embodiment, the circuit board 21 of the rectifier unit 20 is arranged between the heat dissipation component 31 and the transformer unit 10b, and the heat dissipation component 31 is disposed adjacent to the plurality of output filter capacitors 23. In the embodiment, the second winding 11b of the transformer unit 10b is led out from the top side. The transformer unit 10b and the rectifier unit 20 are both placed in an accommodation slot 300 with the heat dissipation component 31 served as a top. The accommodation slot 300 is filled with thermal conductive glue 40 to dissipate heat generated from the transformer unit 10b and the rectifier unit 20. In the embodiment, two U-shaped magnetic cores are used in the transformer unit 10b to form the first magnetic column 121, the second magnetic column 122 and the two magnetic covers 123, 124. The first winding 11a and the second winding 11b are wound around the upper first magnetic column 121, so as to face the heat dissipation component 31. It allows the top side of the second winding 11b to directly contact the heat dissipation component 31 for heat dissipation. In the embodiment, the pins 111 of the second winding 11b are inserted into the upper circuit board 21 of the rectifier unit 20 through the substrate 112. The second winding 11b and the plurality of output filter capacitors 23 are arranged on two opposite sides of the circuit board 21, respectively, so that the plurality of output filter capacitors 23 are disposed adjacent to the heat dissipation component 31 for heat dissipation, and the left side and the right side of the second winding 11b are disposed adjacent to the lateral plates 32, 33, respectively, for heat dissipation. In this way, the second winding 11b in the transformer unit 10b and the filter capacitors 23 in the rectifier unit 20 are disposed adjacent to the heat dissipation component 31 and the side plates 32, 33, respectively. It is beneficial to optimizing the heat dissipation efficiency. Notably, since the number of output filter capacitors 23 is generally large, in some embodiments, a part of the output filter capacitors 23 are disposed on one side attached to the heat dissipation component 31, and the remaining part of the output filter capacitors 23 and the rectifiers 22 are disposed on another side. Certainly, the present disclosure is not limited thereto.

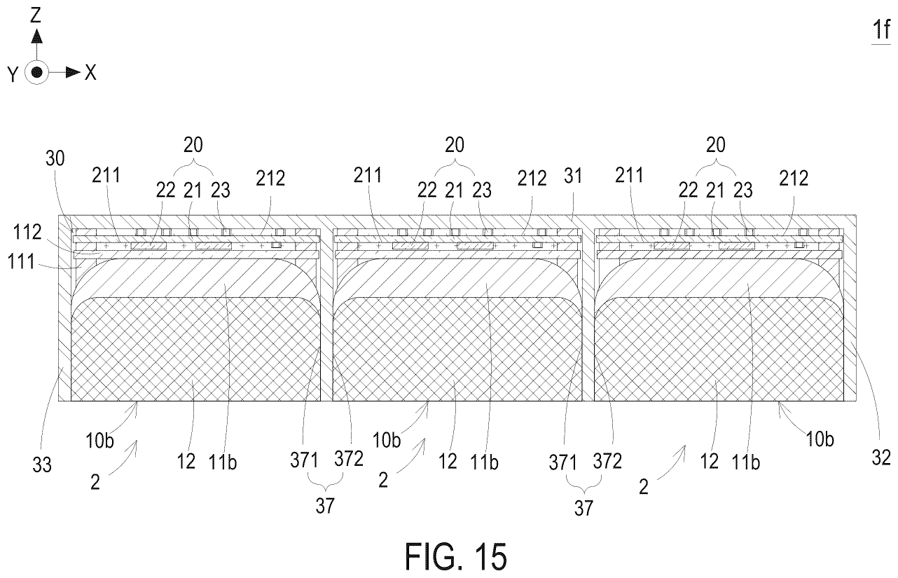

FIG. 15 is a cross-sectional structural view illustrating a power supply device according to a ninth embodiment of the present disclosure. In the embodiment, the structures, elements and functions of the power supply device 1f are similar to those of the power supply device 1e of FIG. 12 to FIG. 14, and are not redundantly described herein. In the embodiment, the power supply device 1f includes three transformer units 10b and three rectifier units 20 that are correspondingly stacked and arranged along the X-axis direction to form three rectification modules 2 adjacent to each other in the accommodation slot 30. Moreover, the heat dissipation component 31 is disposed adjacent to the output filter capacitors 23 of the three transformer units 10b. In the embodiment, the accommodation slot 30 include two lateral plates 37 shared by the three rectification modules 2. The two shared lateral plates 37 are extended downward from the heat dissipation component 31 and located between each adjacent two of the three rectification modules 2. In the embodiment, each of the two shared lateral plates 37 has a first lateral side 371 and a second lateral side 372 opposite to each other. The first lateral side 371 is disposed adjacent to one lateral side of the second winding 11b in the left of each adjacent two of the three rectification modules 2, and the second lateral side 372 is disposed adjacent to one lateral side of the second windings 11b in the right of each adjacent two of the three rectification modules 2. It helps the power supply device 1f to exert the best heat dissipation effect. In other embodiments, the power supply device 1a includes N transformer units 10b and N rectifier units 20 corresponding stacked and arranged along the X-axis direction to form N rectification modules 2. The N rectification modules 2 are arranged adjacently. The heat dissipation component 31 is disposed adjacent to the top sides of output filter capacitors 23 in the N transformer units 10b, and the N rectification modules 2 include (N−1) shared lateral plates 37. Moreover, the (N−1) shared lateral plates 37 are extended downward from the heat dissipation component 31 and located between each adjacent two of the N rectification modules 2. N is an integer, and N≥2. In this way, the plurality of transformer units 10b and the plurality of rectifier units 20 are corresponding stacked and arranged to form the plurality of rectification modules 2, and the plurality of rectifier modules 2 are arranged adjacently. The heat dissipation component 31 is disposed adjacent to the output filter capacitors 23 of the plurality of rectifier units 20 for heat dissipation, and the plurality of shared lateral plates 37 are extended downward from the heat dissipation component 31 and located between each adjacent two of the plurality of rectification modules 2. The first lateral side 371 and the second lateral side 372 of the shared lateral plate 37 are disposed adjacent to the lateral sides of the second winding 11b in each adjacent two of the rectification modules 2, respectively. Thereby, the power supply device 1f can exert the best heat dissipation effect. Certainly, the present disclosure is not limited thereto.

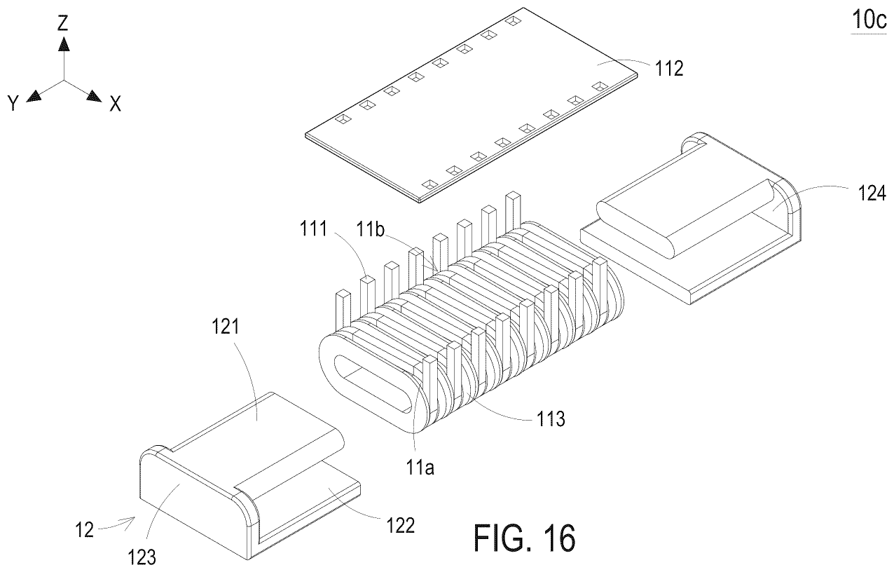

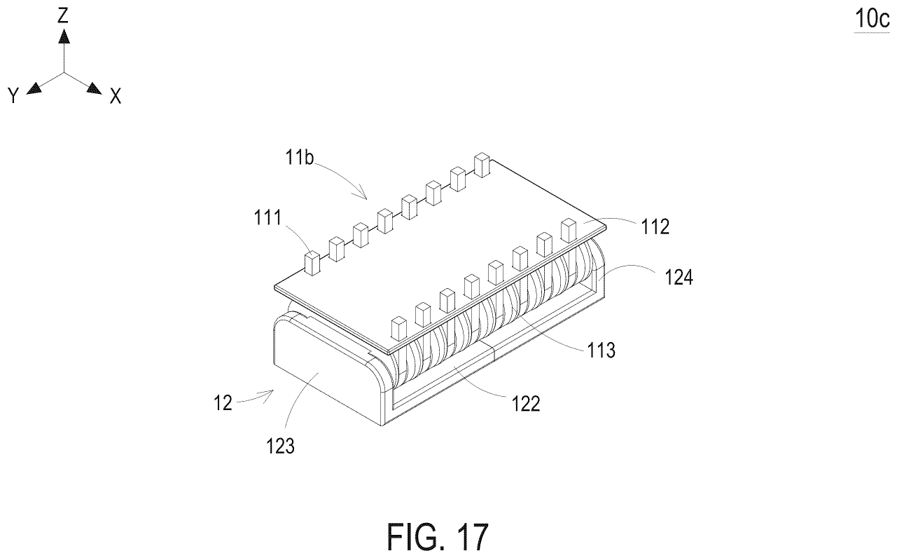

FIG. 16 is a structural exploded view illustrating a transformer unit according to a tenth embodiment of the present disclosure. FIG. 17 is a structural perspective view illustrating the transformer unit according to the tenth embodiment of the present disclosure. In the embodiment, the structures, elements and functions of the transformer unit 10c are similar to those of the transformer unit 10b of FIG. 12 to FIG. 15, and are not redundantly described herein. Preferably but not exclusively, in the embodiment, the second winding 11b is made of litz wire 113 wound thereon, and the pins 111 of the second winding 11b are connected to the circuit board 21 of the rectifier unit 20 through a substrate 112.

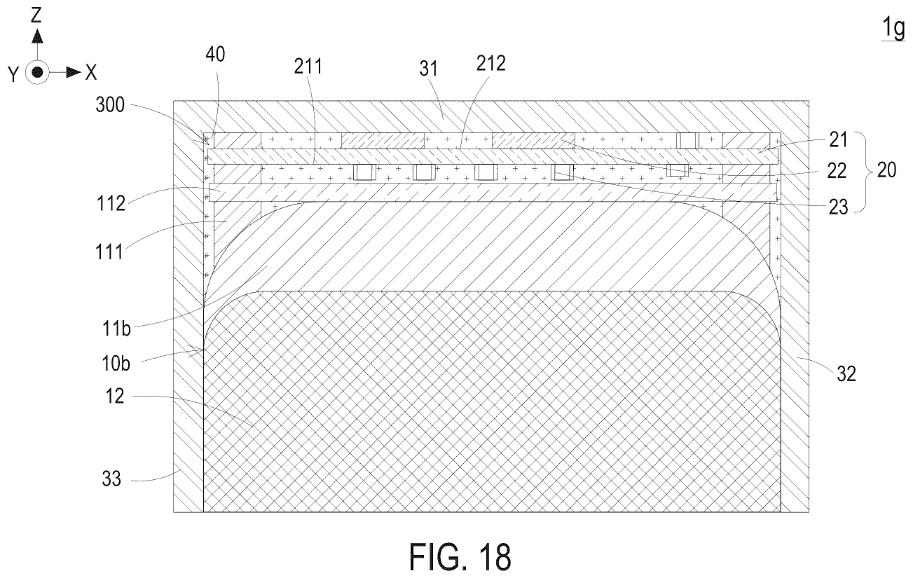

FIG. 18 is a cross-sectional structural view illustrating a power supply device according to an eleventh embodiment of the present disclosure. In the embodiment, the structures, elements and functions of the power supply device 1g are similar to those of the power supply device 1e of FIG. 12 to FIG. 14, and are not redundantly described herein. In the embodiment, the rectifier unit 20 of the power supply device 1g uses, for example, rectifiers 22 with large on-resistance, which have rigorous heat dissipation requirements. The circuit board 21 of the rectifier unit 20 is arranged between the heat dissipation component 31 and the transformer unit 10b. The plurality of rectifiers 22 are disposed on the second side 212 of the circuit board 21, and the heat dissipation component 31 is disposed adjacent to the plurality of rectifiers 22. In the embodiment, the second winding 11b of the transformer unit 10b is led out from the top side, and the transformer unit 10b and the rectifier unit 20 are both accommodated in the accommodation slot 300 with the heat dissipation component 31 served as the top. The pins 111 of the second winding 11b are inserted into the circuit board 21 of the upper rectifier unit 20 through the substrate 112. The second winding 11b and the rectifiers 22 are disposed on two opposite sides of the circuit board 21, respectively, so that the rectifiers 22 are arranged adjacent to the heat dissipation component 31 for heat dissipation, and the left side and right side of the second winding 11b are disposed adjacent to the lateral plates 32, 33 for heat dissipation. In this way, the second winding 11b of the transformer unit 10b and the rectifiers 22 of the rectifier unit 20 are disposed adjacent to the heat dissipation component 31 and the lateral plates 32, 33, respectively. It is beneficial to optimizing the heat dissipation efficiency of the power supply device 1g. Notably, since the number of output filter capacitors 23 is generally large, in the embodiment, the output filter capacitors 23 are disposed on the first side 211 and the second side 212 of the circuit board 21. In this way, a part of the output filter capacitors 23 and the rectifiers 22 disposed on the second side 212 face the heat dissipation component for heat dissipation. Certainly, the present disclosure is not limited thereto and not redundantly described herein.

In summary, the present disclosure provides a power supply device. For the rectification module formed by the transformer unit and the rectifier unit, the windings with heat dissipation requirements in the transformer unit and the output filter capacitors and/the rectifiers in the rectifier unit are disposed adjacent to the heat dissipation component, so that the power supply device can exert the best heat dissipation effect. In some application scenarios, the heat dissipation requirements for the rectifiers are rigorous. For example, in order to save the costs, the rectifiers used in the rectification module have larger on-resistance with more heat generated, so the rectifiers can be arranged adjacent to the heat dissipation component. In other application scenarios, the rectifiers of the rectifier unit are placed on the side of the circuit board facing the transformer to minimize the AC losses. Since the output filter capacitors are the filter capacitors at the output end of the rectifier circuit, the capacitors will have large ripples and serious heat generation in low-voltage and high-current situations, and the temperature has a greater impact on the life of the capacitors. One solution is to add more capacitors, but such an arrangement will take up a certain amount of space. Therefore, if the heat can be well dissipated, it will help improve the overall power density. In the present disclosure, the output filter capacitors with the upward direction are disposed adjacent to the heat dissipation component, or the output filter capacitors are disposed adjacent to the metal plate connected to the heat dissipation component, so that the heat dissipation advantage of the heat dissipation component is fully utilized to take away the heat generated from the output filter capacitors to ensure the life of the output filter capacitors. It allows fewer capacitors to be used to achieve filtering while meeting the heat dissipation requirements and improving the power density. On the other hand, the rectifiers of the rectifier unit are disposed to face the transformer. Since the first harmonic in the secondary current of the transformer mainly flows through the rectifiers, the second harmonic and the above one mainly flow through the filter capacitors. The amplitude of the first harmonic is relatively larger. Therefore, the rectifiers are disposed on the side facing the transformer to form the shortest current loop path, it helps to reduce the loss of the rectifiers and the loss of the rectifier circuit board. Notably, since the number of output filter capacitors is generally large, in some embodiments, a part of the output filter capacitors are disposed on one side attached to the heat dissipation component or the metal lateral plates, and the remaining part of the output filter capacitors and the rectifiers are disposed on another side. When the transformer unit and the rectifier unit are arranged in the X axial direction under the heat dissipation component, U-shaped magnetic cores are used in the transformer unit, and the winding is wound around the upper magnetic column to face the heat dissipation component, so that a part of the winding is disposed adjacent to the heat dissipation component for heat dissipation. Certainly, the winding is not limited to being composed of litz wire or copper foil. In addition, the winding of the transformer unit is connected to the circuit board of the rectifier unit through the pins at the lateral side. The winding pins are inserted into the circuit board of the rectifier unit through the substrate. The windings and the filter capacitors and/or the rectifiers are respectively arranged on opposite sides of the circuit board, so that the filter capacitor and/or the rectifiers are disposed adjacent to the metal plate on the lateral side for heat dissipation. The metal plate can include for example water channels disposed inside. Preferably, the metal plate is integrally formed with the heat dissipation component or disposed separately. The heat dissipation component can also have an edge fitting the shape of the winding. The transformer unit and the rectifier unit are simultaneously placed in an accommodation slot with the heat dissipation component on the top side. The lateral plate of the accommodation slot is the metal plate. The accommodation slot is filled with the thermal conductive glue for at least dissipating the heat from the transformer unit and the rectifier unit. On the other hand, when the winding of the transformer unit is led out from the top side, the rectifier unit is located between the transformer unit and the heat dissipation component. U-shaped magnetic cores are used in the transformer unit, and the winding is wound around the upper magnetic column and the winding pins are inserted into the circuit board of the upper rectifier unit through the substrate. The rectifiers and the output filter capacitors are respectively arranged on opposite sides of the circuit board, so that the output filter capacitors and/or the rectifiers can be disposed adjacent to the heat dissipation component for heat dissipation. The transformer unit and the rectifier unit are simultaneously accommodated in the accommodation slot with the heat dissipation component on the top side. The accommodation slot is filled with the thermal conductive glue to dissipate the heat from the transformer unit and rectifier unit. In that, the winding in the transformer unit and the output filter capacitors and/or the rectifiers in the rectifier unit are disposed adjacent to the heat dissipation component and the lateral plates. It is beneficial to optimize the heat dissipation efficiency of the power supply device. Notably, the terms of “adjacent to” mentioned in the present disclosure does not mean that directly attach or directly contact. It allows to include a certain air gap or insert an insulation interface therebetween. Alternatively, a heat dissipation medium such as a metal plate is disposed therebetween. Furthermore, the heat dissipation component or the lateral plate are all metal plates. In order to meet the security requirements of security regulations, the insulation interface is inserted between some devices and the heat dissipation component. In that, the devices are contacted with or attached to the heat dissipation component. Preferably, the insulation interface can be the insulation tape, the insulation glue, or the insulation pad. The present disclosure is not limited thereto. The transformer unit and the rectifier unit are combined and arranged adjacent to the heat dissipation component to achieve the optimal heat dissipation performance. When the U-shaped magnetic cores are used in the transformer unit, the winding is wound around the upper magnetic column and then disposed adjacent to the heat dissipation component for heat dissipation. The circuit boards of the two rectifier units can be arranged on two opposite sides of the transformer unit, so that the output filter capacitors, which are usually (multilayer ceramic capacitors (MLCC) and/or the rectifiers can be disposed adjacent to the metal plate for heat dissipation. A plurality of transformer units and a plurality of rectifier units are alternately arranged to form a plurality of rectification modules. In case of that the plurality of rectification modules are arranged adjacent to each other, the heat dissipation component is attached to the top side of the windings in the plurality of transformer units for heat dissipation. A plurality of shared lateral plates are extended downward from the heat dissipation component and arranged between each two adjacent ones of the plurality of rectification modules. In each two adjacent ones of the plurality of rectification modules, one side of the shared lateral plate is disposed adjacent to the front rectification module, and another side of the shared lateral plate is disposed adjacent to the lateral side of the winding of the rear rectification module. A fitting arc surface can also be formed between the shared lateral plate and the heat dissipation component to fit the shape of the corresponding winding. A plurality of transformer units and a plurality of rectifier units are stacked correspondingly and arranged in the X axial direction to form a plurality of rectification modules. In case of that the plurality of rectification modules are arranged adjacent to each other, a plurality of accommodation slots are used to accommodate the combination of the transformer unit and the rectifier unit, and the filter capacitors and/or the rectifiers are directly in contact with the heat dissipation component for heat dissipation. Furthermore, a plurality of shared lateral plates are extended downward from the heat dissipation component and arranged between each two adjacent rectification modules. In each two adjacent ones of the plurality of rectification modules, one side of the shared lateral plate is disposed adjacent to the lateral side of the winding of the front rectification module, and another side of the shared lateral plate is disposed adjacent to the lateral side of the winding of the rear rectification module. The arrangement and combination of the components in the transformer unit and the rectifier unit, the heat dissipation component, the heat dissipation device, and the accommodation slot, all help to achieve the optimal heat dissipation performance.

It should be understood that the disclosure needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A power supply device, comprising:
a transformer unit comprising a first winding, a second winding and a magnetic core;
a rectifier unit comprising a circuit board, a plurality of rectifiers and a plurality of output filter capacitors, wherein the circuit board and the transformer unit are disposed adjacent to each other, and the second winding is electrically connected to the circuit board, wherein the circuit board has a first side and a second side opposite to each other, and the first side faces the transformer unit, and
a heat dissipation component, wherein the heat dissipation component covers a rectification module formed by the transformer unit and the rectifier unit.

2. The power supply device according to claim 1, wherein the plurality of rectifiers are disposed on the first side of the circuit board, and at least a part of the plurality of output filter capacitors are disposed on the second side of the circuit board.

3. The power supply device according to claim 2, wherein the plurality of output filter capacitors are all disposed on the second side of the circuit board.

4. The power supply device according to claim 1, wherein the plurality of rectifiers are disposed on the second side of the circuit board, and at least a part of the plurality of output filter capacitors are disposed on the first side of the circuit board.

5. The power supply device according to claim 4, wherein the plurality of output filter capacitors are all disposed on the first side of the circuit board.

6. The power supply device according to claim 1, wherein the magnetic core comprises a first magnetic column and a second magnetic column, the first winding is wound around the first magnetic column, the second winding is wound outside the first winding, and the first magnetic column is located between the heat dissipation component and the second magnetic column.

7. The power supply device according to claim 1, wherein the heat dissipation component is disposed adjacent to a top side of the second winding, and the circuit board and the transformer unit are disposed along a horizontal direction.

8. The power supply device according to claim 7, wherein the heat dissipation component has an edge fitting a shape of the second winding.

9. The power supply device according to claim 7, further comprising two of the rectifier units, wherein the second winding of the transformer unit is electrically connected to the circuit boards of the two rectifier units, respectively, and the circuit boards of the two rectifier units are arranged on two opposite sides of the transformer unit.

10. The power supply device according to claim 1, wherein the circuit board is located between the heat dissipation component and the transformer unit, and the plurality of rectifiers or the plurality of output filter capacitors on the second side of the circuit board are disposed adjacent to the heat dissipation component.

11. The power supply device according to claim 10, wherein the transformer unit and the rectifier unit are both placed in an accommodation slot, and the accommodation slot is filled with thermal conductive glue to at least dissipate heat generated from the transformer unit and the rectifier unit, wherein the heat dissipation component covers a top of the accommodation slot.

12. The power supply device according to claim 11, wherein the accommodation slot comprises a plurality of lateral plates, and the heat dissipation component is served as a top plate of the accommodation slot, so as to form a slot to accommodate the transformer unit and the rectifier unit.

13. The power supply device according to claim 12, wherein the plurality of lateral plates are integrally formed with the heat dissipation component.

14. The power supply device according to claim 11, wherein the accommodation slot comprises a plurality of lateral plates and a top plate for forming a slot to accommodate the transformer unit and the rectifier unit, and the heat dissipation component covers the top plate.

15. The power supply device according to claim 11, wherein each of the plurality of lateral plates and/or the top plate of the accommodation slot is a metal plate for transferring heat to the heat dissipation component.

16. The power supply device according to claim 15, wherein the metal plate comprises a flow channel disposed therein.

17. The power supply device according to claim 1, comprising N transformer units and N rectifier units arranged correspondingly to form N rectification modules, wherein the N rectification modules are accommodated in an accommodation slot, and the accommodation slot comprises a plurality of lateral plates, wherein (N−1) of the lateral plates are shared by the N rectification modules, wherein N is an integer, and N≥2.

18. The power supply device according to claim 6, wherein the magnetic core comprises two magnetic covers, and the first magnetic column and the second magnetic column are connected between the two magnetic covers.

19. The power supply device according to claim 1, wherein the second winding is made of copper foil, and pins of the second winding are connected to the circuit board through a substrate.

20. The power supply device according to claim 1, wherein the second winding is made of litz wire wound thereon, and pins of the second winding are connected to the circuit board through a substrate.

21. The power supply device according to claim 1, wherein the heat dissipation component is a cold plate.
